(19) United States
(12) Patent Application Publication
(10) Pub. No.: US 2025/0118628 A1
(43) Pub. Date: Apr. 10, 2025

(54) HEAT DISSIPATION STRUCTURE OF HIGH-POWER CHIP POWER SUPPLY MODULE

(71) Applicant: SHANGHAI METAPWR ELECTRONICS CO., LTD, Shanghai (CN)

(72) Inventors: Qingdong CHEN, Shanghai (CN); Shouyu HONG, Shanghai (CN); Jianhong ZENG, Shanghai (CN); Yahong Xiong, Shanghai (CN)

(73) Assignee: SHANGHAI METAPWR ELECTRONICS CO., LTD, Shanghai (CN)

(21) Appl. No.: 18/907,578

(22) Filed: Oct. 6, 2024

(30) Foreign Application Priority Data
Oct. 6, 2023 (CN) 202311276798.8

(51) Int. Cl. H01L 23/427; H01L 23/40

(52) U.S. Cl. CPC H01L 23/427; H01L 23/4006; H01L 2023/4043; H01L 2023/4087

(57) ABSTRACT

A heat dissipation structure of a high-power chip power supply module is provided. The heat dissipation structure comprises a first motherboard, a second motherboard, a high-power chip module, a power supply module and a top heat dissipation device. The power supply module comprises at least one heating power component. The power supply module is provided with a heat dissipation surface. The heating power component is arranged adjacent to the heat dissipation surface. The heat dissipation structure further comprises a vapor chamber and a longitudinal thermal conductor. The vapor chamber is in thermal conduction with the heat dissipation face, and the vapor chamber is in thermal conduction with the top heat dissipation device through the longitudinal thermal conductor.

### CROSS-REFERENCE TO RELATED APPLICATION

This application claims the priority benefit of China application serial no. 202311276798.8 filed on Oct. 6, 2023. The entirety of the above-mentioned patent application is hereby incorporated by reference herein and made a part of this specification.

### TECHNICAL FIELD

The invention relates to a high-frequency power supply, in particular to a heat dissipation structure of a high-power chip power supply module.

### DESCRIPTION OF RELATED ART

Due to the fact that the artificial intelligence computing power is larger and larger, power consumption of a computing power chip such as a CPU, TPU, a GPU and the like (collectively referred to as XPU) becomes larger and larger, and current is larger and larger. In a traditional smart card, a horizontal power supply (LPD-Lateral Power Delivery) at the same surface of the power supply module and the XPU cannot meet the trend that the requirement of the power supply current becomes larger and larger, so that the power supply module starts to turn to the vertical power supply (VPD-Vertical Power Delivery), that is, the power supply module is under the XPU.

Meanwhile, due to the fact that the number of XPU digital signals is increased, an intelligent card in a traditional vertical plugging PCIE card form limits the processing of signals and power of the XPU; the large intelligent card starts to develop from an upright type to a recumbent statue; and the recumbent intelligent card is collectively referred to as an OAM card. Due to the fact that the height between the sleeper type intelligent card and the system motherboard is very limited, usually between 5 mm and 10 mm, the height needs to comprise the thickness of the power supply module and the thickness of the heat dissipation device for heat dissipation of the power supply module at the same time, so that the space for the heat dissipation device is very limited. The vertical power supply (referred to as OAM-VPD) industry of the recumbent intelligent card is still in an exploration stage, and no mature technology can be used. In the simplest way, the heat of the power supply module is transmitted to the intelligent card motherboard, then the heat is transmitted to one side of the XPU through the via hole of the intelligent card motherboard, and heat dissipation is carried out through the radiator of the XPU. Therefore, the high-frequency power semiconductor of the power supply module is usually arranged on the face, close to the intelligent card motherboard, of the power supply module in the prior art. The high-frequency power semiconductor of the power supply module comprises DrMOS or SPS; the DrMOS is an abbreviation of an integrated semiconductor of the driver and the MOSFET; and the SPS is short for the Smart Power Stage. The structure not only enables the heat dissipation thermal resistance of the power supply module to be large, but also improves the temperature of the XPU, thereby affecting the processing capability of the XPU.

Therefore, the application provides an effective and practical OAM-VPD power supply and heat dissipation overall solution.

### SUMMARY

The application aims to provide a heat dissipation structure of a power supply module of a high-power chip, in particular to an OAM-VPD power supply and heat dissipation solution. The heating power component in the power supply module is arranged at the position other than the pin surface, and an additional heat dissipation channel is provided, so that the heat generated by the power supply module is prevented from influencing the operation of the XPU; and under the cooperation of the transverse thermal conductor and the longitudinal thermal conductor, heat generated by the power supply module is more effectively conducted to the heating dissipation device while the heat transfer capacity and the fastening capacity are considered.

In order to achieve the purpose, the application provides a heat dissipation structure of a high-power chip power supply module comprises a first motherboard, a second motherboard, a high-power chip module, a power supply module and a top heat dissipation device, wherein the first motherboard comprises a first surface and a second surface which are opposite to each other, and the second motherboard comprises a third surface and a fourth surface which are opposite to each other, the high-power chip module is arranged on the first surface, the power supply module is arranged on the second surface, and an assembly body of the first motherboard, the high-power chip module and the power supply module is assembled on the third surface of the second motherboard in a recumbent statue, the power supply module is located between the first motherboard and the second motherboard, the top heat dissipation device is in thermal conduction with the high-power chip module, the power supply module corresponds to the high-power chip module in a vertical mode, and the power supply module comprises at least one heating power component;

The power supply module is provided with a heat dissipation surface, and the heating power component is arranged adjacent to the heat dissipation surface;

The heat dissipation structure further comprises at least one vapor chamber, the vapor chamber is thermally connected to the heat dissipation surface, and the vapor chamber is thermally connected to the top heat dissipation device by means of the longitudinal thermal conductor. Preferably, the heat dissipation structure, further comprising a plurality of fasteners; and

a plurality of longitudinal thermal conductors are arranged; and the combination of the longitudinal thermal conductor and the fastener is used for fastening the vapor chamber and the first motherboard on the top heat dissipation device; the longitudinal thermal conductor comprises a limiting end, a cylindrical heat pipe and a fastening structure; the limiting end and the fastening structure are arranged at the two ends of the cylindrical heat pipe respectively; the limiting end is in large-area thermal connection with the vapor chamber; the fastening structure is fixedly connected with the fastener; and the cylindrical heat pipe penetrates through the first motherboard and the vapor chamber.

Preferably, the longitudinal thermal conductor is provided with a closed cavity, a phase change material is arranged in the closed cavity, or the material of the longitudinal thermal conductor comprises at least one of graphene or carbon nanotubes.

Preferably, the vapor chamber can be a copper material, a copper-graphite alloy or an ultra-thin VC plate containing a phase change material.

Preferably, the limiting end is a cap; the fastener is a screw; the fastening structure is provided with a thread; the top heating dissipation device is provided with a plurality of stepped holes; the fastener and the fastening structure are fixedly connected in the stepped hole; and a thermal conduction filler is arranged in a gap between the inner wall of the stepped hole and the fastening structure.

Preferably, the heat dissipation structure, further comprises a plurality of fasteners, wherein the plurality of longitudinal thermal conductors are arranged; the longitudinal thermal conductor comprises a cylindrical heat pipe; the fastener is used for fixing the longitudinal thermal conductor on the top heat dissipation device; and the longitudinal thermal conductor penetrates through the first motherboard, and the longitudinal thermal conductor and the vapor chamber are fixedly connected through welding.

Preferably, the vapor chamber is arranged between the second motherboard and the power supply module, and the vapor chamber is in thermal conduction with the second motherboard.

Preferably, a through window is formed in the vapor chamber, an input electrode of the power supply module is electrically connected with a second motherboard through the through window, and the vapor chamber is in thermal conduction with the second motherboard through a thermal interface material.

Preferably, a through hole is formed in the second motherboard, a back heat dissipation device is arranged on the fourth surface, the vapor chamber is provided with a thermal column matched with the through hole in shape, and the vapor chamber is in thermal conduction with the back heat dissipation device through the bottom face of the thermal column.

Preferably, the power supply module is in thermal conduction with the third surface, the vapor chamber is arranged on the fourth surface, the vapor chamber corresponds to the power supply module vertically, a thermal conduction via hole is formed in the second motherboard, the power supply module and the vapor chamber are in thermal conduction through the thermal conduction through hole, and the longitudinal thermal conduction device also penetrates through the second motherboard.

Preferably, the cross section of the cylindrical heat pipe is circular, the fastener is a screw, and one end of the cylindrical heat pipe is further provided with a fastening structure with threads.

Preferably, the cross section of the cylindrical heat pipe is annular, the fastener is a screw penetrating through the cylindrical heat pipe, and threads are arranged on the inner wall of the cylindrical heat pipe.

Preferably, the heat dissipation structure, further comprising a transverse thermal conductor, and the transverse thermal conductor is arranged on the vapor chamber; and the vapor chamber plays a role in reinforcing ribs.

Preferably, the transverse thermal conductor is provided with a closed cavity, a phase change material is arranged in the closed cavity, or the material of the transverse thermal conductor comprises at least one of graphene or carbon nanotubes.

Preferably, the heat dissipation structure, further comprising a shell and a plurality of fasteners; the vapor chamber is arranged between the second motherboard and the power supply module, a motherboard through hole is formed in the second motherboard, a back heat dissipation device is arranged on the fourth surface, the vapor chamber is provided with a thermal column matched with the motherboard through hole in shape, and the vapor chamber is in thermal conduction with the back heat dissipation device through the bottom face of the thermal column; the fastener is used for fixing the top heat dissipation device, the first motherboard and the second motherboard on the shell; the fastener penetrates through the top heat dissipation device, the first motherboard and the second motherboard; and an elastic buffer layer is arranged between the back heat dissipation device and the shell.

Preferably, the heat dissipation structure further comprises a transverse thermal conductor, the transverse thermal conductor is arranged on the vapor chamber, and the longitudinal thermal conductor comprises a flat longitudinal thermal conductor; the transverse thermal conductor and the flat longitudinal thermal conductor are integrally formed or fixedly connected to form a bendable thermal conductor, the longitudinal thermal conductor is arranged on at least one side of the first motherboard, a mounting hole is formed in the end of the longitudinal thermal conductor, and the longitudinal thermal conductor is mounted on the top heat dissipation device through a fastener.

Preferably, the bendable thermal conductor is provided with a closed cavity, a phase change material is arranged in the closed cavity, or the material of the bendable thermal conductor comprises at least one of graphene or carbon nanotubes; and the width of the bendable thermal conductor is not less than 10 mm, the thickness is less than 5 mm, and the thermal conduction coefficient is not less than 1000 W/(m·K).

Preferably, fins are arranged on the vapor chamber, the power supply module comprises the plurality of sub-modules, and the sub-modules are in thermal conduction with the vapor chamber; the side faces of the sub-modules are in thermal conduction with the fins; the fins are used for heat dissipation of the side faces of the sub-modules.

The fins and the vapor chamber are integrally formed, or the fins and the vapor chamber are thermally connected.

Preferably, the top heat dissipation device comprises a top liquid cooling plate, the vapor chamber is a bottom liquid cooling plate, the longitudinal thermal conductor is a liquid guide hose, the top liquid cooling plate, the bottom liquid cooling plate and the liquid guide hose are interior connected in the cooling liquid cavities, and cooling liquid is arranged in the cooling liquid cavity. Preferably, the cooling liquid chamber is a closed self-circulation chamber and the cooling liquid is a phase change cooling liquid, or the cooling liquid chamber is liquid connected to a coolant pump.

Compared with the prior art, the application has the following beneficial effects:
(1) The heating element in the power supply module is arranged at the position except the pin surface, and an additional heat dissipation channel is provided, so that the heating of the power supply module is prevented from influencing the operation of the XPU.
(2) The heat of the power supply module is more effectively conducted to the main radiator and/or the auxiliary radiator in a limited height space through cooperation of the transverse thermal conductor and the longitudinal thermal conductor of the vapor chamber According to the application, the heat and force composite structural design is further carried out on the uniform temperature plate and/or the longitudinal thermal conductor, so that the heat transfer and fastening effects are realized at the same time.
(3) Through the arrangement of the liquid cooling circulation system, the thickness of the high-power chip and the power supply module device is further reduced while heat dissipation is guaranteed.

### BRIEF DESCRIPTION OF THE DRAWINGS

FIG. 1 is a schematic diagram of the prior art.

FIGS. 2A, 2B, 2C, 2D, 3A, 3B, 3C, 3D, 3E, 4A, 4B, 5A, 5B are schematic diagrams of a first embodiment of the present invention.

FIG. 6 is a schematic diagram of embodiment 2 of the present invention.

FIG. 7 is a schematic diagram of Embodiment 3 of the present invention.

FIG. 8A and FIG. 8B are schematic diagrams of a fourth embodiment of the present invention.

FIG. 9A and FIG. 9B are schematic diagrams of a fifth embodiment of the present invention.

### DESCRIPTION OF THE EMBODIMENTS

The present application discloses various embodiments or examples of implementing the thematic technological schemes mentioned. To simplify the disclosure, specific instances of each element and arrangement are described below. However, these are merely examples and do not limit the scope of protection of this application. For instance, a first feature recorded subsequently in the specification formed above or on top of a second feature may include an embodiment where the first and second features are formed through direct contact, or it may include an embodiment where additional features are formed between the first and second features, allowing the first and second features not to be directly connected. Additionally, these disclosures may repeat reference numerals and/or letters in different examples. This repetition is for brevity and clarity and does not imply a relationship between the discussed embodiments and/or structures. Furthermore, when a first element is described as being connected or combined with a second element, this includes embodiments where the first and second elements are directly connected or combined with each other, as well as embodiments where one or more intervening elements are introduced to indirectly connect or combine the first and second elements.

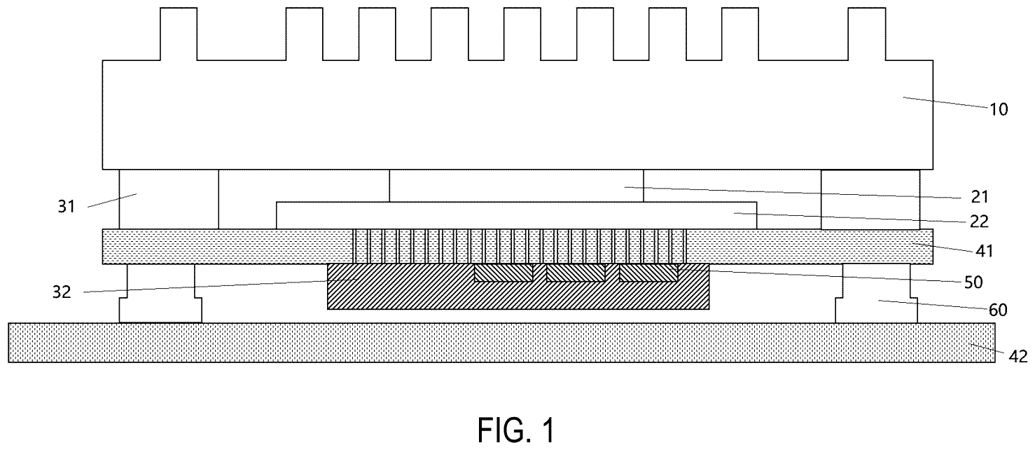

As shown in FIG. 1, an OAM-VPD structure and a heat dissipation structure commonly used at present comprise a first motherboard, a second motherboard, a main radiator 10, a high-power chip module, a high-speed signal connector 60 and a power supply module 31/32, wherein the first motherboard, namely the intelligent card motherboard 41, is at least provided with a high-power chip module on the upper surface of the first motherboard; the high-power chip module comprises at least one XPU wafer 21 and an XPU substrate 22; a high-speed signal connector 60 is arranged on each of the two sides of the lower surface of the first motherboard, so that the high-power chip module can be directly or indirectly electrically connected to the second motherboard; the second motherboard, namely the system motherboard 42. A power supply module 31 is provided on the upper surface of the first motherboard and supplies power to the XPU in a horizontal power supply mode; and a power supply module 32 is arranged on the lower surface of the first motherboard, and supplies power to the XPU by adopting a vertical power supply mode. a main radiator 10 which is placed above the XPU and is attached to the heat dissipation surface of the XPU; and the main radiator 10 can also be referred to as a top heat dissipation device and is used for dissipating heat of the XPU and the power supply module 31. The power supply module 32 is located on the lower surface of the first motherboard, so that the power supply module 32 is closer to the XPU, the transmission impedance is low, the dynamic response is fast, and the dynamic characteristic requirement of the XPU can be well met. However, because the height of the space between the first motherboard and the second motherboard is limited, the heat dissipation device cannot be installed for the power supply module 32. Therefore, a structure for heat dissipation of a power supply module adopting a vertical power supply mode is urgently needed.

### Embodiment 1

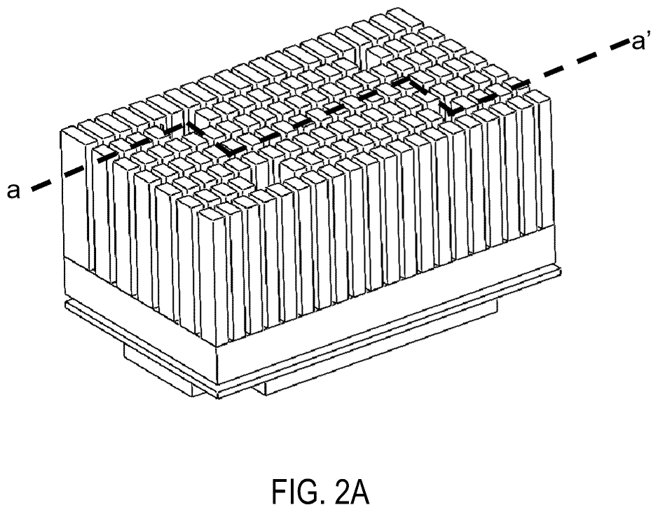

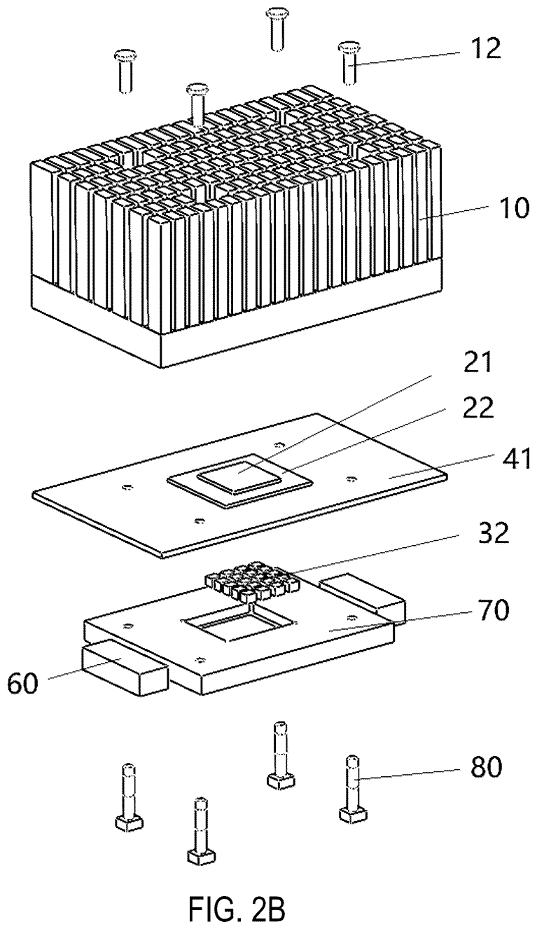

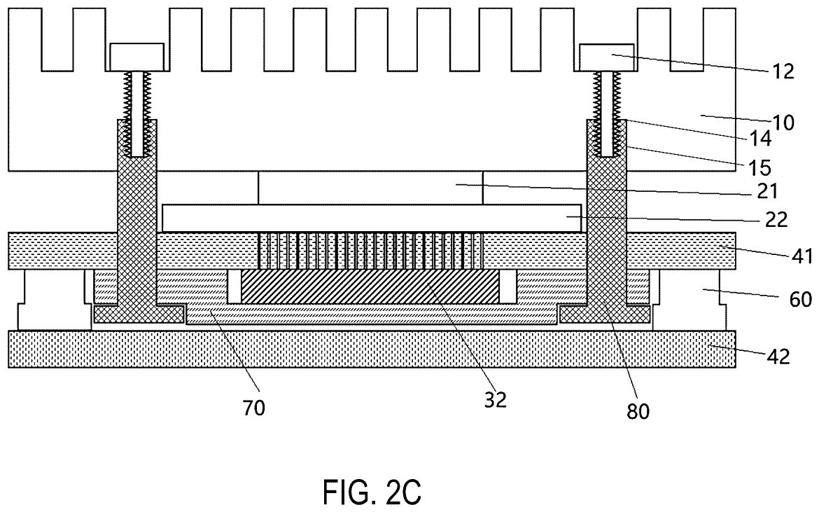

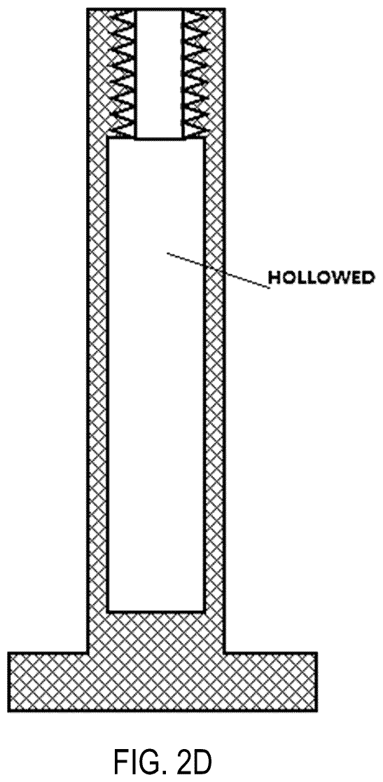

As shown in FIG. 2A to FIG. 2D, FIG. 2A is a schematic diagram of a heat dissipation structure of a high-power chip using a vertical power supply mode and a power supply module thereof according to an embodiment of the present disclosure. FIG. 2B is an exploded view of FIG. 2A. FIG. 2C is a schematic cross-sectional view aa′ of FIG. 2A, and FIG. 2D is a structural diagram of a longitudinal thermal conductor 80.

The heat dissipation structure of the high-power chip power supply module comprises a first motherboard, a main radiator 10, a vapor chamber 70 and a thermal and force composite body.

The first motherboard is an intelligent card motherboard 41; and at least one high-power chip module is installed on the upper surface of the first motherboard; the high-power chip module comprises at least one XPU wafer 21 and an XPU substrate 22; the power consumption of the XPU wafer is generally larger than 500 W. A high-speed signal connector 60 is arranged on each of the two sides of the lower surface of the first motherboard; the high-speed signal connector 60 can directly or indirectly electrically connect the high-power chip module to the second motherboard, the second motherboard is the system motherboard 42. The power supply module 32 is further arranged on the lower surface of the first motherboard, and the low-voltage large current is provided for the XPU from the lower surface of the first motherboard to the upper surface of the first motherboard through the via hole of the first motherboard; the power supply module 32 can be a single integrated module or is formed by integrating a plurality of small module arrays through a first motherboard, and the power consumption of the power supply module 32 is usually greater than 50 W.

The main radiator 10 is placed above the XPU and is attached to the heat dissipation surface of the XPU; the main radiator 10 can also be referred to as a top heat dissipation device and provides heat dissipation for the XPU.

The vapor chamber 70 is used for transversely conducting the heat of the power supply module 32 and cooperating with other structural members to further conduct heat to the heat dissipation device; a thermal conduction interface material (not shown in the figure) is arranged between the vapor chamber 70 of the embodiment and the heat dissipation surface of the power supply module 32, and heat generated by the power supply module is homogenized in the vapor chamber 70, so that the heat is conveniently led out to the radiator. The vapor chamber 70 is generally secured to the main radiator 10 by four thermal and force composites penetrating the intelligent card motherboard and assists the main radiator 10 in good thermal contact with the XPU.

The thermal and force composite body comprises a longitudinal thermal conductor 80 and a screw 12, the main radiator 10 comprises a stepped hole 14 penetrating up and down, the vapor chamber 70 and the first motherboard both comprise corresponding straight holes penetrating up and down, and the longitudinal thermal conductor 80 penetrates through the vapor chamber 70 and the first motherboard through the straight hole to reach the stepped hole 14 of the main radiator 10; a screw 12 penetrates through the top of the main radiator 10, mechanical fastens the vapor chamber 70 and the main radiator 10 with the longitudinal thermal conductor 80, and meanwhile, the XPU and the main radiator 10 are further mechanically fastened; and meanwhile, the heat of the vapor chamber 70 is conducted to the main radiator 10 through the longitudinal thermal conductor 80. The cover cap of the longitudinal connector is in large-area thermal contact with the vapor chamber 70, and the thermal conduction area between the longitudinal thermal conductor 80 and the vapor chamber is further increased; and filler such as thermal conduction silicone is filled between the large-diameter part 15 of the stepped hole 14 and the outer surface of the longitudinal thermal conductor 80, so that a gap between the large-diameter part 15 and the outer surface of the longitudinal thermal conductor 80 is reduced, and the thermal conduction resistance is reduced. The thermal and force composite body better realizes mechanical fastening between the main radiator 10 and the vapor chamber 70, and realizes heat dissipation of the power supply module by means of the vapor chamber and the main radiator 10.

In the embodiment, heat generated by the power supply module 32 can be conducted to the longitudinal thermal conductor 80 through the vapor chamber 70, then the heat is conducted to the main radiator 10 through the longitudinal thermal conductor 80, and the vapor chamber 70 and the longitudinal thermal conductor 80 are welded together to reduce the contact impedance between the vapor chamber 70 and the longitudinal thermal conductor 80. Further, the structure of the heat pipe integrated with the longitudinal thermal conductor 80 is cylindrical, which may be a hollow chamber structure, and the chamber structure is filled with a phase change material, as shown in FIG. 2D. After the heat is transferred to the longitudinal thermal conductor 80, the internal phase change material is heated from a liquid state to an gaseous state and rises to the top of the longitudinal thermal conductor 80, then the phase change material changes from a gaseous state to a liquid state through cooling of the main radiator 10 and flows back to the bottom of the longitudinal thermal conductor 80, and heat generated by the power supply module 32 is dissipated through the vapor chamber 70, the longitudinal thermal conductor 80 and the main radiator 10 in a reciprocating cycle. Due to the fact that the thickness of the vapor chamber is thin, in order to meet the transverse thermal conduction, the vapor chamber can be a copper material, a copper graphite alloy, or an ultrathin VC plate containing a phase change material (a VC plate, namely a vapor chamber, similar to a cylindrical heat pipe in a longitudinal thermal conductor), or a combination of a vapor chamber and a flat heat pipe considering heat transfer and fastening capacity.

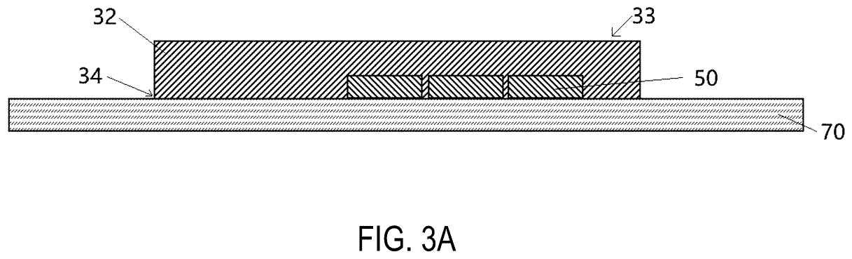

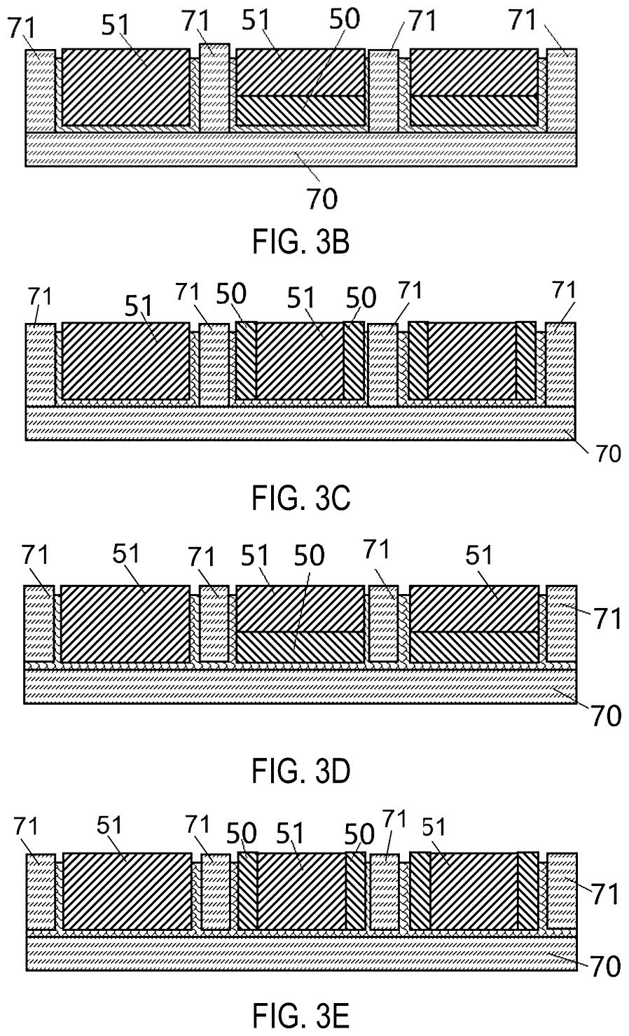

Due to the fact that the power semiconductor is collectively referred to as the MOS 50, the power semiconductor is the device with the highest thermal density in the whole power supply module 32. The position of the MOS 50 in the power supply module 32 is attached to the vapor chamber 70. As shown in FIG. 3A, one surface of the power supply module 32 in electrical contact with the intelligent card motherboard 41 is defined as a pin surface 33 or a bottom surface; the MOS 50 used by the power supply module 32 accounts for more than 50% of the total heating value of the power supply module 32, and therefore the MOS 50 should be arranged adjacent to other surfaces of the power supply module 32; for example, the top surface and the side surface of the power supply module referred to as the heat dissipation surface 34, so that a heat dissipation channel is conveniently added subsequently (the top surface in FIG. 3A is downward and the bottom surface is shown upwards).

In a preferred embodiment, as shown in FIGS. 3B˜3E, the power supply module 32 has a plurality of sub-modules 51, and the vapor chamber 70 is not only in thermal contact with the top surface of the sub-module 51, but also in thermal contact with the side surface of the sub-module 51, so as to increase the module heat dissipation channel, thereby solving the problem of continuous increase of the heat density of the power supply module 32. Therefore, the vapor chamber 70 further comprises vertical fins 71; the vapor chamber 70 is integrally formed with the vertical fins 71, as shown in FIG. 3B and FIG. 3C. In another embodiment, the vertical fins 71 are fixedly connected by gluing or welding, as shown in FIG. 3D and FIG. 3E. The vertical fin 71 is thermally connected to the side surface of the sub-module 51 by means of a heat-conducting connection material, thereby increasing the heat dissipation channel of the module 51, facilitating the improvement of the heat dissipation effect, being more beneficial to the uniformity of the internal temperature of the sub-module 51, and avoiding the generation of hot spots. In the sub-module 51, the side heat source may be a magnetic element, or an MOS 50 mounted on a side surface of the magnetic element, as shown in FIG. 3C and FIG. 3E.

In some other embodiments, due to the fact that the power consumption of the XPU becomes larger and larger, the heat dissipation requirement of the power supply module 32 is larger and larger, and the heat dissipation requirement of the power supply module cannot be met through thermal connection between the heat and force composite body and the main radiator 10. Therefore, a continuous thermal conduction path is needed between the vapor chamber 70 and the main radiator 10, and the thermal conduction capability is further improved.

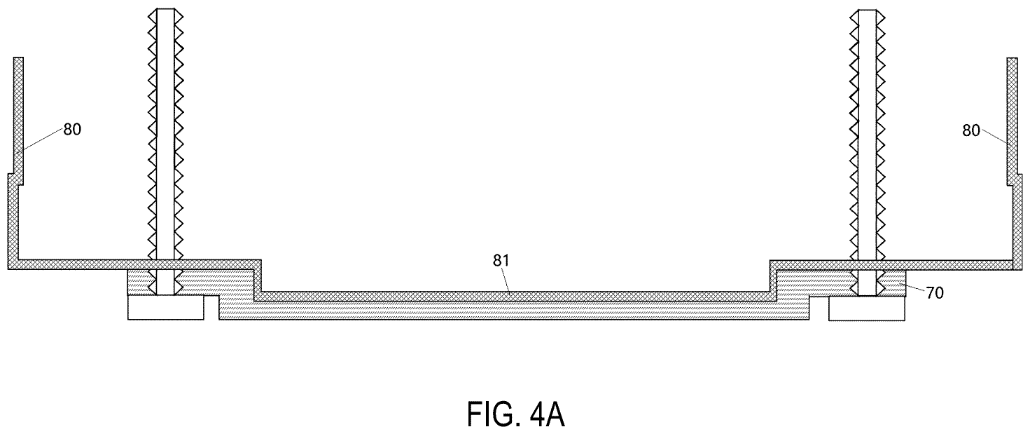

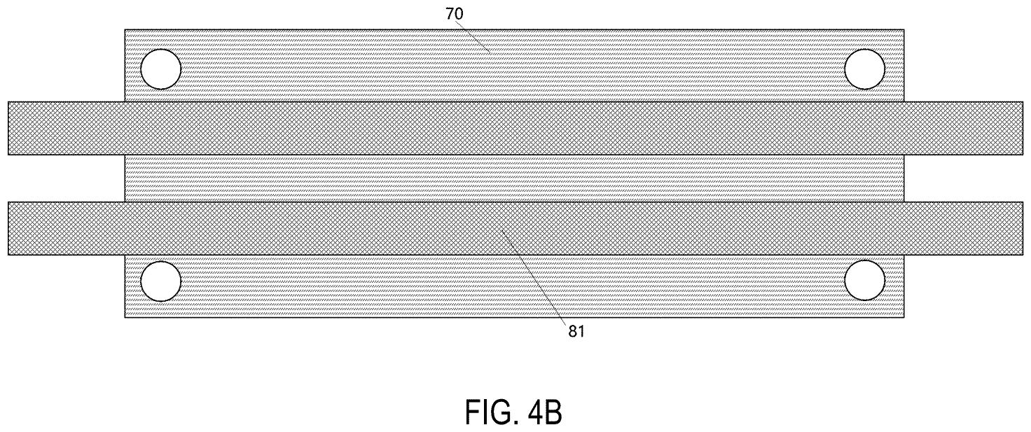

In this embodiment, a combination of a vapor chamber 70 and a flat heat pipe is used, as shown in FIG. 4A and FIG. 4B. FIG. 4A is a side view of a combination of a vapor chamber 70 and a flat heat pipe, and FIG. 4B is a top view of FIG. 4A. The flat heat pipe comprises a transverse thermal conductor 81 and a longitudinal thermal conductor 80; and the transverse thermal conductor 81 transversely extends in the horizontal direction of the vapor chamber 70. The longitudinal thermal conductor 80 extends from the transverse thermal conductor 81 extends to the main radiator 10 in the vertical direction. The transverse thermal conductor 81 and the longitudinal thermal conductor 80 can be of an integrally formed structure, that is, the longitudinal thermal conductor 80 is formed by bending the two ends of the flat heat pipe, or can be riveted, bonded or welded together. Due to the fact that the positions of the XPU wafer and the power supply module 32 arranged on the intelligent card motherboard 41, are usually used to transmit the power or the signals, and therefore the longitudinal thermal conductor 80 can only extend to the main radiator 10 from the two sides of the power supply module 32; and further, the longitudinal thermal conductor 80 is in thermal contact with the main radiator 10, so that the thermal resistance between the vapor chamber 70 and the main radiator 10 is further reduced. Here, the thickness of the flat heat pipe is less than 5 mm or even 3 mm, and the width of the flat heat pipe is at least 10 mm or even 20-30 mm. In order to guarantee the good transmission capacity of the vapor chamber, the flat heat pipe can be a hollow chamber filled with the phase change material or a flat belt comprising graphene and carbon nanotubes, and the thermal conduction capacity of the flat heat pipe should be as high as 1000 W/(m*K) or above. Similarly, if the mechanical fastening capability needs to be considered, the vapor chamber 70 shown in FIG. 2C can be used in combination with the structure shown in FIG. 2C, and specifically, the vapor chamber 70 in FIG. 2C is replaced with the combination of the vapor chamber 70 and the flat heat pipe in FIG. 4A, so that the thermal conduction capability and the mechanical fastening capability can be considered.

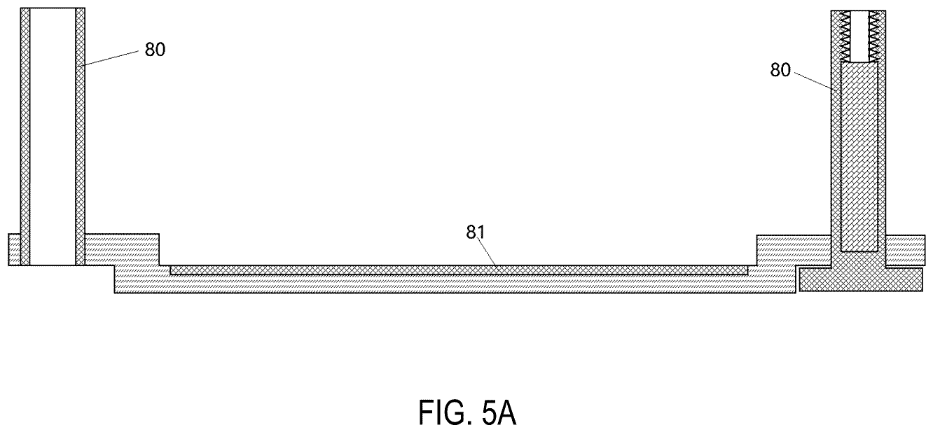

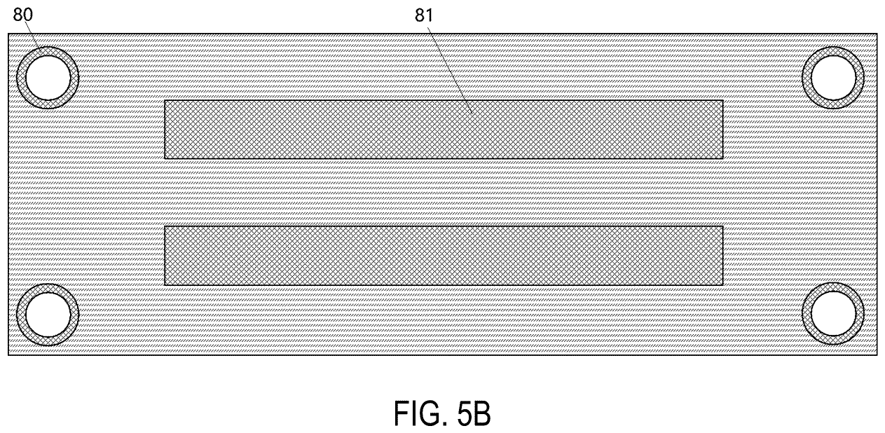

In a preferred embodiment, the combination of the vapor chamber 70 and the flat heat pipe can also be as shown in FIGS. 5A and 5B. FIG. 5A is a side view of a combination of the vapor chamber 70 and the flat heat pipe. FIG. 5B is a top view of FIG. 5A. The longitudinal thermal conducting member 80 on the left side in FIG. 5A is a sleeve-shaped heat pipe with an annular cross section. After the high-strength bolt penetrates through the sleeve-shaped heat pipe, the high-strength bolt is matched with the nut for force fixation. For example, the longitudinal thermal conductor 80 on the right side in FIG. 5A is provided with a screw 12 above the heat pipe; in an actual embodiment, the longitudinal thermal conductor 80 on the left side or the right side in FIG. 5A adopts the same structure. Due to the fact that the heat pipe usually adopts a metal with low structural strength, such as copper, the heat pipe is easy to deform if the heat pipe bears a large force. In FIG. 5B, the flat heat pipe is flatly attached to the vapor chamber 70, so that the combination of the vapor chamber 70 and the flat heat pipe gives consideration to the force strength and the thermal yield, and the situation that the heat pipe is deformed caused by the stress is avoided; and specifically, the vapor chamber 70 plays a role of the reinforcing rib, and the flat heat pipe plays a role of the transverse thermal conductor.

### Embodiment 2

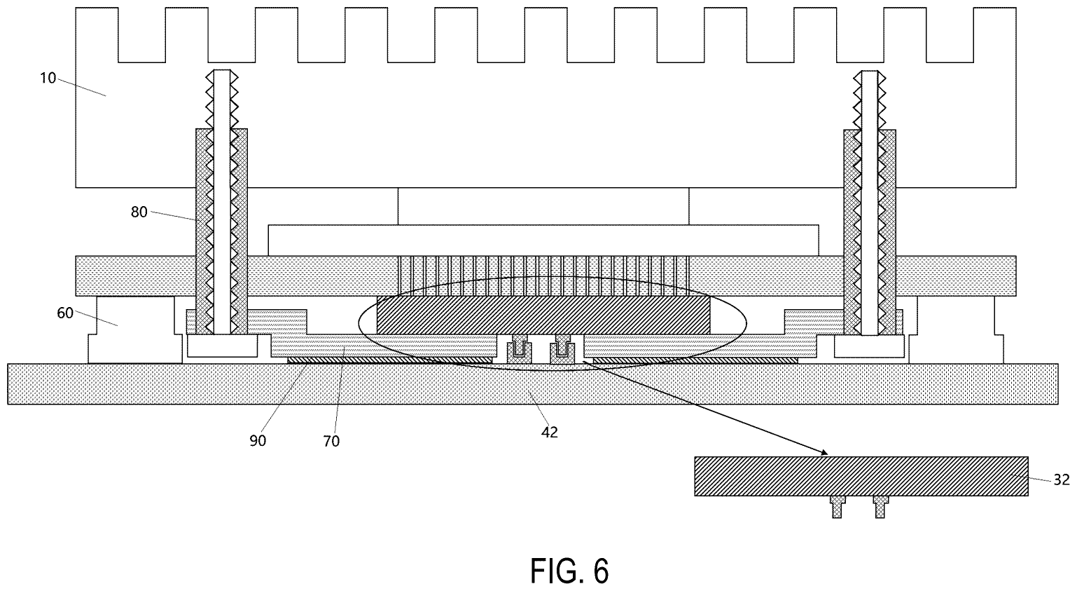

As shown in FIG. 6, a through window is reserved on the vapor chamber 70, so that the power supply module 32 and the system motherboard 42 can be electrically connected through the through window, and the connection mode is preferably a connector mode; and the connector mode is similar to the high-speed signal connector 60, such as an enlarged schematic diagram of the power supply module 32 in FIG. 6. A power supply module contact pin or a power supply module socket is arranged below the power supply module 32; a corresponding power supply socket or power supply plug is arranged on the upper surface of the system motherboard 42; a system motherboard power supply jack can also be arranged on the system motherboard 42 for inserting pins below the power supply module 32 to obtain electricity; and the system motherboard power supply jack penetrates through the thickness of the system motherboard. Therefore, the high-voltage input electrode of the power supply module 32 can also realize vertical power transmission nearby through the plug-in part mode, the large current limitation of the low input voltage is broken through, and the high-voltage flash distance limitation of the high input voltage is broken through. The input voltage of the power supply module 32 can be lower than 5V, can also be as high as 12V, 48V, 400V, 800V or 1200V. The vapor chamber can serve as a GND grounding electrode of the power supply module 32, is electrically connected with the system motherboard and further increases the current capability, the high-speed signal connector 60 of the intelligent card can not be provided with a power pin, so that the processing capability of the high-speed signal is facilitated, and the communication capacity is increased.

In the present implementation, the height of the high-speed signal connector 60 is reduced, so that the distance between the vapor chamber 70 and the system motherboard 42 is reduced, and a thermal conduction interface material 90 is added between the vapor chamber 70 and the system motherboard 42. Although the thermal conductivity of the thermally conduction interface material 90 is lower than the thermal conductivity of the vapor chamber 70, a heat dissipation path is added to the power supply module 32, that is, the part of heat of the part of the power supply module 32 can be dissipated by means of the system motherboard 42, thereby achieving a better thermal conduction effect on the power supply module 32.

### Embodiment 3

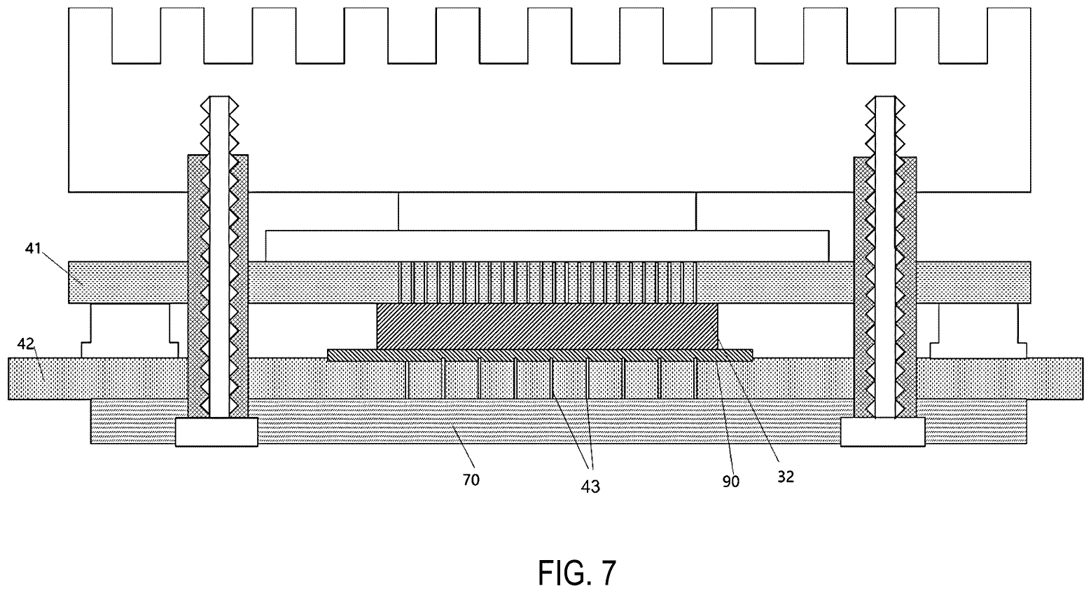

As shown in FIG. 7, in some application scenarios, the height between the intelligent card motherboard 41 and the system motherboard 42 is further reduced (such as reduced to 5 mm), so that the vapor chamber 70 needs to be arranged on the interior or the lower surface of the system motherboard 42. According to the embodiment, the vapor chamber 70 located on the lower surface of the system motherboard 42 are shown. The power supply module 32 is directly attached to the system motherboard 42 through the thermal conduction interface material 90, and a plurality of thermal conduction through holes 43 are formed in the system motherboard 42 and are used for realizing thermal conduction between the power supply module 32 and the vapor chamber 70. Heat can be further transmitted to the main radiator 10 through the heat and force composite body, and the heat and force composite body simultaneously penetrates through the vapor chamber 70, the system motherboard 42 and the intelligent card motherboard 41 or can bend and extend the flat heat pipe on the vapor chamber 70 to the main radiator 10 to transfer heat.

### Embodiment 4

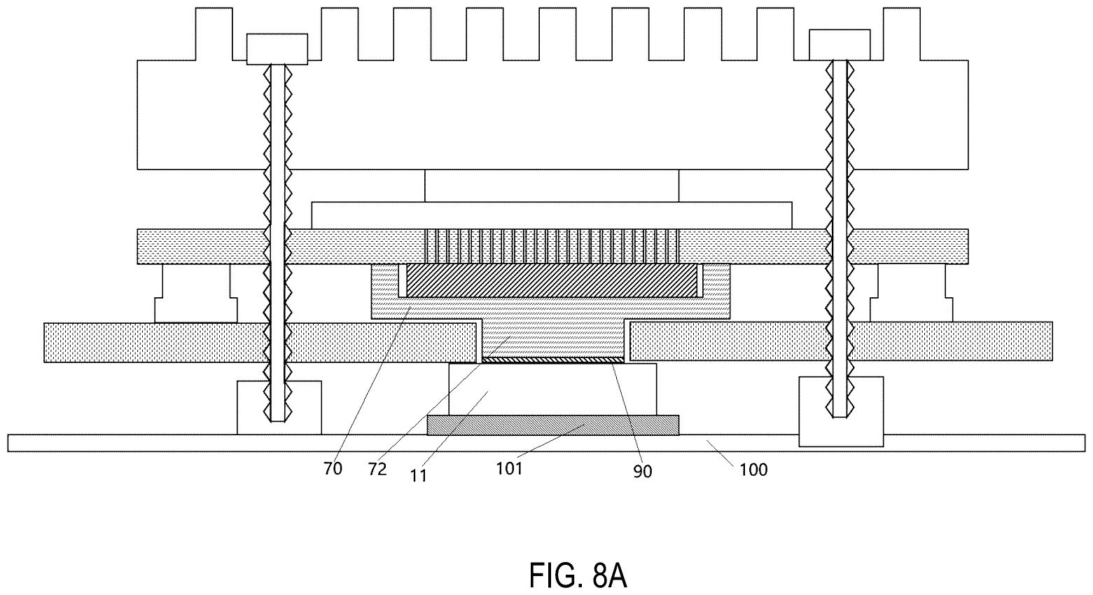

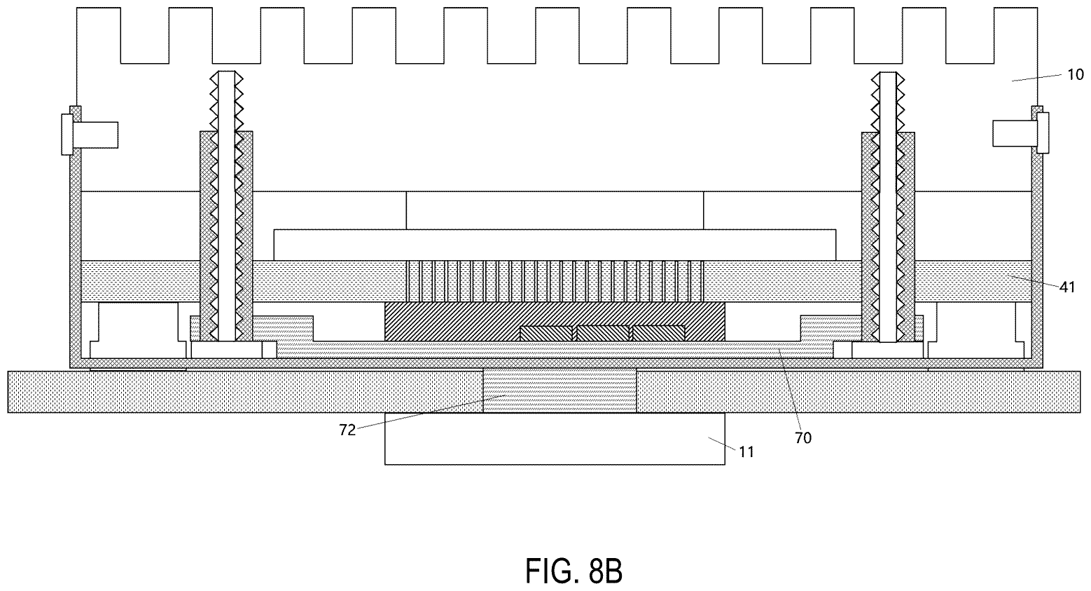

As shown in FIG. 8A, an auxiliary radiator 11 is arranged on the back surface of the system motherboard 42 of the embodiment, and the vapor chamber 70 can preferentially conduct heat generated by the power supply module 32 to the auxiliary radiator 11. The specific structure of the auxiliary radiator 11 is as follows: a thermal column 72 with a small cross-section convex can be arranged on the part of the large-area vapor chamber 70; and the thermal column 72 penetrates through the through hole in the system motherboard 42, and the shape of the through hole is matched with the shape of the thermal column 72. The power supply module 32 conducts heat to the auxiliary radiator 11 through the thermal column 72, and the main radiator 10 is fixed to the shell 100 through screws. An elastic buffer layer 101 can be arranged between the auxiliary radiator 11 and the shell 100 if it's needed, which is used to absorb the longitudinal structural tolerances between the main radiator 10 and the shell 100, and to keep the enough pressure between the structures.

As shown in FIG. 8B, in a preferred embodiment, three different heat dissipation paths are arranged: the vapor chamber 70 conducts heat to the auxiliary radiator 11 through the thermal column 72; the vapor chamber 70 conducts heat to the main radiator 10 through a heat and force composite body penetrating through the intelligent card motherboard 41; and the vapor chamber 70 locks the bendable flat heat pipe on the vapor chamber 70 on the radiator 10, so that more heat is conducted to the main radiator 10.

### Embodiment 5

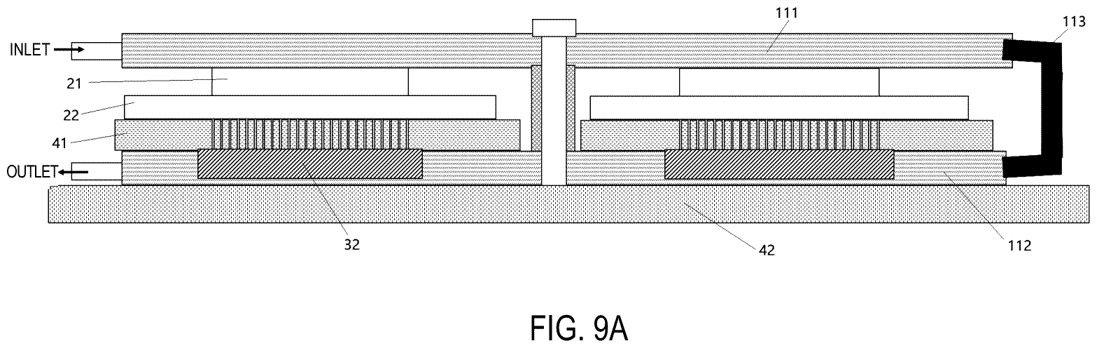

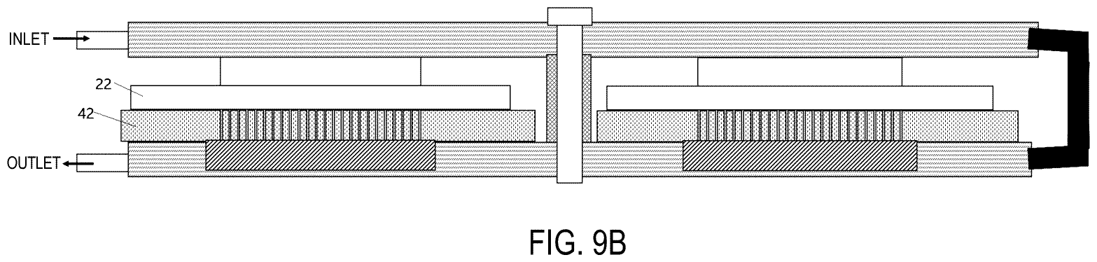

Along with the fact that the power consumed by the XPU wafer becomes larger and larger, the output power of the power supply module is higher and higher, and the challenge of heat dissipation is larger and larger; and traditional air-cooling heat dissipation becomes a bottleneck, and the heat dissipation mode is gradually changed from air-cooling heat dissipation to liquid-cooling heat dissipation. FIG. 9A provides a system liquid-cooling heat dissipation structure. The structure comprises a top liquid cooling plate 111 and a bottom liquid cooling plate 112, wherein the top liquid cooling plate 111 is located above the XPU wafer 21 and is used for dissipating heat of the XPU wafer; the bottom liquid cooling plate 112 is located below the power supply module 32 and used for dissipating heat of the power supply module; and vertical liquid path connection is achieved between the two liquid cooling plates through a liquid guide hose 113. Preferably, the top liquid cooling plate 111 are shared to heat dissipation by a plurality of XPU wafers; the bottom liquid cooling plate 114 are shared to heat dissipation by a plurality of power supply modules 32; and the two liquid cooling plates are connected in series through the liquid guide hose 113 on the same side of the two liquid cooling plates.

In one application scenario, the entire system may include a plurality of structures similar to those shown in FIG. 9A, wherein the liquid paths of the cooling liquid may be connected in parallel or in series. Generally, the volume of the air-cooling radiator is relatively large, so that the heat exchange area between the radiator and the air is increased, and the heat dissipation requirement can be met. The liquid cooling plate can adopt a thin structure, such as less than 50 mm, the heat exchange capacity is improved by increasing the flow rate and pressure through a power device such as a cooling liquid pump. The power devices are arranged outside the system motherboard and do not occupy the height size of the system motherboard. On the other hand, since the plurality of intelligent cards share the same liquid cooling plate, the intelligent card motherboard 41 does not need to be provided with screw holes for fixing the liquid cooling plate, so that the plane size of the intelligent card motherboard 41 is saved; only some supporting columns need to be arranged between the intelligent card motherboard 41 to fix the top liquid cooling plate and the bottom liquid cooling plate; or the supporting column can be arranged on the periphery of the system motherboard, and is not limited herein. Due to the fact that a plurality of intelligent cards share the top liquid cooling plate, it's ensured that the thermal conduction interface material between the XPUs and the top liquid cooling plate 111 is thin enough to achieve an excellent heat dissipation effect.

According to an installation mode, a liquid cooling plate can be used as a carrier, a plurality of intelligent cards are attached to the top liquid cooling plate 111 respectively, and each intelligent card is fixed to the top liquid cooling plate 111 through screws; then a supporting column 114 and a bottom liquid cooling plate 112 are installed; and finally, a top liquid cooling plate 111 and a bottom liquid cooling plate 112 are fixed through screws. In some other embodiments, the two liquid path plate liquid plates can also be connected in series through the liquid guide hose 113 on the two opposite sides of the two liquid cooling plates; or the two liquid cooling plates can be connected in parallel through the liquid guide hose 113.

In some other embodiments, the top liquid cooling plate 111 and the bottom liquid cooling plate 112 can also be connected by connecting the two liquid cooling plates to form a self-circulation closed cavity, and the internal liquid is a phase change material.

In some other embodiments, the system only includes the system motherboard 42, but does not include the intelligent card motherboard 41; the plurality of XPU substrates 22 are directly attached to the plurality of system motherboard 42 respectively, and the formed structure is shown in FIG. 9B. In the embodiment, the plurality of XPU wafers continue to share the top liquid cooling plate; and the plurality of system motherboard 42 share the bottom liquid cooling plate. In an extended embodiment, the plurality of system motherboard 42 may be combined into one system motherboard.

What is claimed is:

1. A heat dissipation structure of a high-power chip power supply module, comprising a first motherboard, a second motherboard, a high-power chip module, a power supply module and a top heat dissipation device, wherein
the first motherboard comprises a first surface and a second surface which are opposite to each other;
the second motherboard comprises a third surface and a fourth surface which are opposite to each other;
the high-power chip module is arranged on the first surface;
the power supply module is arranged on the second surface,
wherein an assembly body of the first motherboard, the high-power chip module and the power supply module is assembled on the third surface of the second motherboard in a recumbent statue, the power supply module is located between the first motherboard and the second motherboard, the top heat dissipation device is in thermal conduction with the high-power chip module, the power supply module corresponds to the high-power chip module in a vertical mode, and the power supply module comprises at least one heating power component,
wherein the power supply module is provided with a heat dissipation surface, and the heating power component is arranged adjacent to the heat dissipation surface,
wherein the heat dissipation structure of the high-power chip power supply module further comprises at least one vapor chamber, the vapor chamber is thermally connected to the heat dissipation surface, and the vapor chamber is thermally connected to the top heat dissipation device by means of the longitudinal thermal conductor.

2. The heat dissipation structure of the high-power chip power supply module according to claim 1, further comprising a plurality of fasteners,
wherein a plurality of longitudinal thermal conductors are arranged, and the combination of the longitudinal thermal conductor and the fastener is used for fastening the vapor chamber and the first motherboard on the top heat dissipation device,
wherein the longitudinal thermal conductor comprises a limiting end, a cylindrical heat pipe and a fastening structure; wherein
the limiting end and the fastening structure are arranged at the two ends of the cylindrical heat pipe respectively;
the limiting end is in large-area thermal connection with the vapor chamber; the fastening structure is fixedly connected with the fastener; and
the cylindrical heat pipe penetrates through the first motherboard and the vapor chamber.

3. The heat dissipation structure of the high-power chip power supply module according to claim 1, wherein the longitudinal thermal conductor is provided with a closed cavity, a phase change material is arranged in the closed cavity, or the material of the longitudinal thermal conductor comprises at least one of graphene or carbon nanotubes.

4. The heat dissipation structure of the high-power chip power supply module according to claim 1, wherein the vapor chamber can be a copper material, a copper-graphite alloy or an ultra-thin VC plate containing a phase change material.

5. The heat dissipation structure of the high-power chip power supply module according to claim 2, wherein the limiting end is a cap; the fastener is a screw; the fastening structure is provided with a thread; the top heating dissipation device is provided with a plurality of stepped holes; the fastener and the fastening structure are fixedly connected in the stepped hole; and a thermal conduction filler is arranged in a gap between the inner wall of the stepped hole and the fastening structure.

6. The heat dissipation structure of the high-power chip power supply module according to claim 1, further comprising a plurality of fasteners, wherein the plurality of longitudinal thermal conductors are arranged,
wherein the longitudinal thermal conductor comprises a cylindrical heat pipe,
wherein the fastener is used for fixing the longitudinal thermal conductor on the top heat dissipation device,
wherein the longitudinal thermal conductor penetrates through the first motherboard, and the longitudinal thermal conductor and the vapor chamber are fixedly connected through welding.

7. The heat dissipation structure of the high-power chip power supply module according to claim 6, wherein the vapor chamber is arranged between the second motherboard and the power supply module, and the vapor chamber is in thermal conduction with the second motherboard.

8. The heat dissipation structure of the high-power chip power supply module according to claim 6, wherein a through window is formed in the vapor chamber, an input electrode of the power supply module is electrically connected with a second motherboard through the through window, and the vapor chamber is in thermal conduction with the second motherboard through a thermal interface material.

9. The heat dissipation structure of the high-power chip power supply module according to claim 6, wherein a through hole is formed in the second motherboard, a back heat dissipation device is arranged on the fourth surface, the vapor chamber is provided with a thermal column matched with the through hole in shape, and the vapor chamber is in thermal conduction with the back heat dissipation device through the bottom face of the thermal column.

10. The heat dissipation structure of the high-power chip power supply module according to claim 6, wherein the power supply module is in thermal conduction with the third surface, the vapor chamber is arranged on the fourth surface, the vapor chamber corresponds to the power supply module vertically, a thermal conduction via hole is formed in the second motherboard, the power supply module and the vapor chamber are in thermal conduction through the thermal conduction through hole, and the longitudinal thermal conduction device also penetrates through the second motherboard.

11. The heat dissipation structure of the high-power chip power supply module according to claim 6, wherein the cross section of the cylindrical heat pipe is circular, the fastener is a screw, and one end of the cylindrical heat pipe is further provided with a fastening structure with threads.

12. The heat dissipation structure of the high-power chip power supply module according to claim 6, wherein the cross section of the cylindrical heat pipe is annular, the fastener is a screw penetrating through the cylindrical heat pipe, and threads are arranged on the inner wall of the cylindrical heat pipe.

13. The heat dissipation structure of the high-power chip power supply module according to claim 6, further comprising a transverse thermal conductor, and the transverse thermal conductor is arranged on the vapor chamber; and the vapor chamber plays a role in reinforcing ribs.

14. The heat dissipation structure of the high-power chip power supply module according to claim 13, wherein the transverse thermal conductor is provided with a closed cavity, a phase change material is arranged in the closed cavity, or the material of the transverse thermal conductor comprises at least one of graphene or carbon nanotubes.

15. The heat dissipation structure of the high-power chip power supply module according to claim 1, further comprising a shell and a plurality of fasteners;
wherein the vapor chamber is arranged between the second motherboard and the power supply module, a motherboard through hole is formed in the second motherboard, a back heat dissipation device is arranged on the fourth surface, the vapor chamber is provided with a thermal column matched with the motherboard through hole in shape, and the vapor chamber is in thermal conduction with the back heat dissipation device through the bottom face of the thermal column;
wherein the fastener is used for fixing the top heat dissipation device, the first motherboard and the second motherboard on the shell; the fastener penetrates through the top heat dissipation device, the first motherboard and the second motherboard; and an elastic buffer layer is arranged between the back heat dissipation device and the shell.

16. The heat dissipation structure of the high-power chip power supply module according to claim 1, further comprising a transverse thermal conductor,
wherein the transverse thermal conductor is arranged on the vapor chamber, and the longitudinal thermal conductor comprises a flat longitudinal thermal conductor;
wherein the transverse thermal conductor and the flat longitudinal thermal conductor are integrally formed or fixedly connected to form a bendable thermal conductor, the longitudinal thermal conductor is arranged on at least one side of the first motherboard, a mounting hole is formed in the end of the longitudinal thermal conductor, and the longitudinal thermal conductor is mounted on the top heat dissipation device through a fastener.

17. The heat dissipation structure of the high-power chip power supply module according to claim 16, wherein the bendable thermal conductor is provided with a closed cavity, a phase change material is arranged in the closed cavity, or the material of the bendable thermal conductor comprises at least one of graphene or carbon nanotubes; and the width of the bendable thermal conductor is not less than 10 mm, the thickness is less than 5 mm, and the thermal conduction coefficient is not less than 1000 W/(m·K).

18. The heat dissipation structure of the high-power chip power supply module according to claim 1, wherein fins are arranged on the vapor chamber, the power supply module comprises the plurality of sub-modules, and the sub-modules are in thermal conduction with the vapor chamber; wherein
the side faces of the sub-modules are in thermal conduction with the fins;
the fins are used for heat dissipation of the side faces of the sub-modules;
the fins and the vapor chamber are integrally formed, or the fins and the vapor chamber are thermally connected.

19. The heat dissipation structure of the high-power chip power supply module according to claim 1, wherein the top heat dissipation device comprises a top liquid cooling plate, the vapor chamber is a bottom liquid cooling plate, the longitudinal thermal conductor is a liquid guide hose, the top liquid cooling plate,
wherein the bottom liquid cooling plate and the liquid guide hose are interior connected in the cooling liquid cavities, and cooling liquid is arranged in the cooling liquid cavity.

20. The heat dissipation structure of the high-power chip power supply module according to claim 19, wherein the cooling liquid chamber is a closed self-circulation chamber, and the cooling liquid is a phase change cooling liquid, or the cooling liquid chamber is liquid connected to a coolant pump.
